(19) United States
(12) Patent Application Publication
(10) Pub. No.: US 2015/0180472 A1
(43) Pub. Date: Jun. 25, 2015

(54) DISPLAY DEVICE AND INFRARED TOUCH MODULE THEREOF

(71) Applicants: Qisda (Suzhou) Co., Ltd., Suzhou (CN); Qisda Corporation, Taoyuan (TW)

(72) Inventors: YUNG-CHUN SU, New Taipei City (TW); YING-TSUNG TSAI, Taoyuan City (TW)

(21) Appl. No.: 14/531,885

(22) Filed: Nov. 3, 2014

(30) Foreign Application Priority Data
Dec. 20, 2013 (TW) 102147569

(51) Int. Cl. H03K 17/96; H05K 1/02; G06F 3/042

(52) U.S. Cl. CPC H03K 17/9638; H03K 17/9631; H03K 17/9629; G06F 3/042; H05K 1/0274; H03K 2217/96015; H05K 2201/10128; H05K 2201/10121

(57) ABSTRACT

A display device includes an infrared touch module, a back casing and a display panel. The infrared touch module includes a light guide member, a circuit board and an infrared transmitter. The circuit board is disposed on the light guide member and the infrared transmitter is disposed on an arrangement plane of the circuit board. The light guide member defines a touch plane and an angle is included between the arrangement plane and the touch plane, wherein the included angle is larger than 0 degree and smaller than or equal to 90 degrees. The back casing and the light guide member are combined with each other so that an accommodating space is formed between the light guide member and the back casing. The display panel is disposed in the accommodating space and has a display plane, wherein the display plane is substantially parallel to the touch plane.

### BACKGROUND OF THE INVENTION

1. Field of the Invention

The present invention relates to a display device and an infrared touch module thereof, and more particularly, to a display device and an infrared touch module with a reduced-width frame.

2. Description of the Prior Art

Please refer to FIG. 1. FIG. 1 is a partial cross-section diagram of a display device 1 according to the prior art. As shown in FIG. 1, the display device 1 includes an infrared touch module 10, a back casing 12, a display panel 14, a protective glass 16 and a middle frame 18. The infrared touch module 10 includes a light guide member 100, a circuit board 102 and an infrared transmitter 104. The circuit board 102 is disposed on the light guide member 100. The infrared transmitter 104 is disposed on an arrangement plane 1020 of the circuit board 102. The protective glass 16 is disposed on the light guide member 100, and provides a touch plane 1000 on one surface thereof. The middle frame 18 is fixed on the light guide member 100 through a screw 20. The circuit board 102 is disposed between the middle frame 18 and the light guide member 100. The back casing 12 and the middle frame 18 are combined with each other so that an accommodating space 22 is formed between the light guide member 100 and the back casing 12. The display panel 14 is disposed in the accommodating space 22, and has a display plane 140, wherein the display plane 140 of the display panel 14 is substantially parallel to the touch plane 1000 of the protective glass 16.

As shown in FIG. 1, since the circuit board 102 is disposed on the light guide member 100 in the way that the arrangement plane 1020 of the circuit board 102 is substantially parallel to the touch plane 1000 of the protective glass 16, the frame of the display device 1, i.e. one side of the light guide member 100, has a given width W1. Thus, the display device 1 according to the prior art is not suitable for the narrow frame design. Moreover, during the assembly of the display device 1, the middle frame 18 needs to be fixed on the light guide member 100 through the screw 20 first, and the back casing 12 is then combined with the middle frame 18. In this way, it not only takes more assembly time but also increases the manufacturing cost due to the numbers of the components being assembled.

### SUMMARY OF THE INVENTION

One of the purposes of this invention is to provide a display device and an infrared touch module with a reduced-width frame so that aforementioned problems can be resolved.

According to one embodiment, the display device of this invention includes an infrared touch module, a back casing and a display panel. The infrared touch module includes a light guide member, a circuit board and an infrared transmitter. The circuit board is disposed on the light guide member and the infrared transmitter is disposed on an arrangement plane of the circuit board. The light guide member defines a touch plane and an angle is included between the arrangement plane and the touch plane, wherein the included angle is larger than 0 degree and smaller than or equal to 90 degrees. The back casing and the light guide member are combined with each other so that an accommodating space is formed between the light guide member and the back casing. The display panel is disposed in the accommodating space and has a display plane, wherein the display plane is substantially parallel to the touch plane.

According to another embodiment, the infrared touch module includes a light guide member, a circuit board and an infrared transmitter. The light guide member defines a touch plane. The circuit board is disposed on the light guide member. The infrared transmitter is disposed on an arrangement plane of the circuit board, and an angle is included between the arrangement plane and the touch plane, wherein the included angle is larger than 0 degree and smaller than or equal to 90 degrees.

In conclusion, in this invention the angle included between the arrangement plane of the circuit board and the touch plane is larger than 0 degree and smaller than or equal to 90 degrees. That is the arrangement plane of the circuit board is not substantially parallel to the touch plane so that the frame width of the display device can be effectively decreased. Thus, the display device of this invention is suitable for the narrow frame design. Besides, in this invention the back casing and the light guide member are combined with each other directly so that the middle frame of the display device according to the prior art can be leaved out. In this way, the assembly efficiency can be effectively improved and the manufacturing cost can be decreased since less numbers of components are required.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a partial cross-section diagram of a display device according to the prior art.

FIG. 2 is a three dimensional diagram of a display device according to an embodiment of the present invention.

FIG. 3 is a cross-section diagram of the display device according to the embodiment of the present invention taken along the A-A line shown in FIG. 2.

### DETAILED DESCRIPTION

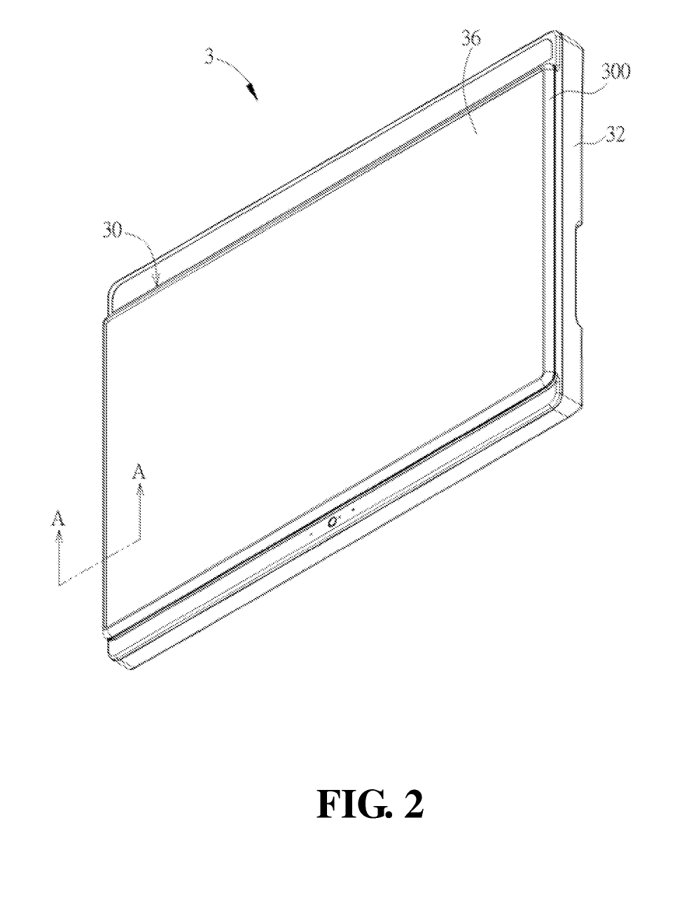

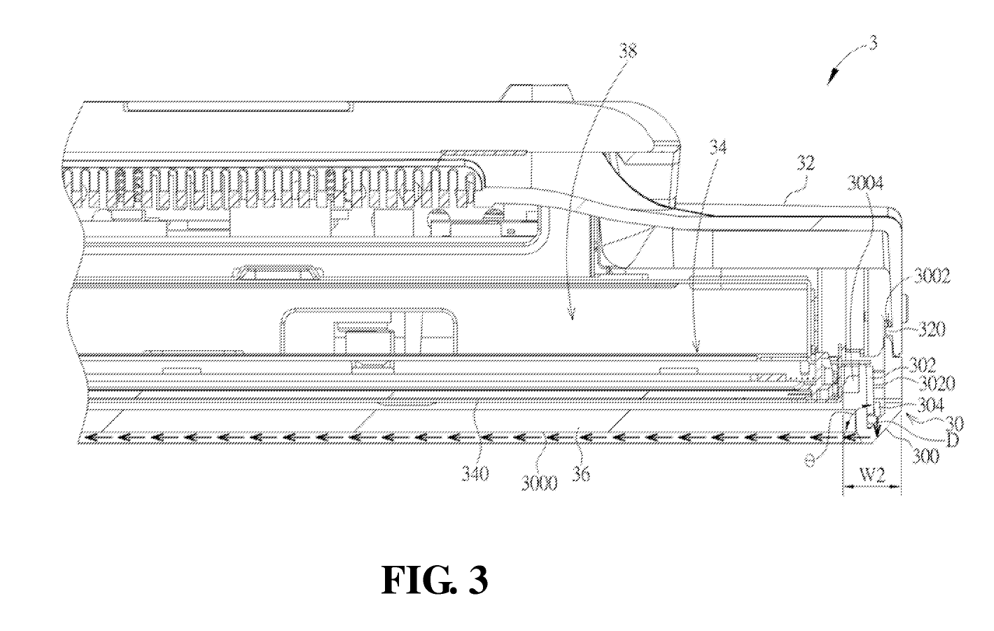

Please refer to FIG. 2 and FIG. 3. FIG. 2 is a three dimensional diagram of a display device according to an embodiment of the present invention. FIG. 3 is a cross-section diagram of the display device according to the embodiment of the present invention taken along the A-A line shown in FIG. 2. As shown in FIG. 2 and FIG. 3, the display device 3 includes an infrared touch module 30, a back casing 32, a display panel 34 and a protective glass 36. In the present embodiment, the display device 3 may be a Liquid Crystal Display (LCD) device, a plasma display device or other display device, and the display panel 34 may be a corresponding LCD panel, a plasma panel or other display panel.

The infrared touch module 30 includes a light guide member 300, a circuit board 302 and an infrared transmitter 304. The infrared transmitter 304 may be an infrared LED, but is not so limited. The circuit board 302 is disposed on the light guide member 300. The infrared transmitter 304 is disposed on an arrangement plane 3020 of the circuit board 302. Besides, the light guide member 300 defines a touch plane 3000. The protective glass 36 is disposed on the light guide member 300, and the protective glass 36 has a surface that lies substantially the same as the aforementioned touch plane 3000 defined by the light guide member 300. As shown in FIG. 3, the light output direction D of the infrared transmitter 304 is substantially parallel to the arrangement plane 3020 of the circuit board 302 so that the infrared ray emitted by the infrared transmitter 304 is guided to the touch plane 3000 through the light guide member 300.

The back casing 32 and the light guide member 300 are combined with each other so that an accommodating space 38 is formed between the light guide member 300 and the back casing 32. In the present embodiment, the light guide member 300 has a first combination part 3002, and the back casing 32 has a second combination part 320. Thus, the light guide member 300 and the back casing 32 are combined with each other through the first combination part 3002 of the light guide member 300 and the second combination part 320 of the back casing 32. The first combination part 3002 may be a latch or a hole, and the second combination part 320 may be a hole or a latch which corresponds to the first combination part 3002 based on the practical application. The back casing 32 and the light guide member 300 therefore are combined with each other by the latch and the hole. Please note that the back casing 32 and the light guide member 300 may be combined together by a screw or in other way, and not limited to the latch and the hole.

The display panel 34 is disposed in the accommodating space 38, and has a display plane 340. The display plane 340 is substantially parallel to the touch plane 3000 defined by the light guide member 300. In the present embodiment, the light guide member 300 has a limitation part 3004, and the limitation part 3004 may be a protruding rib. When the display panel 34 is disposed in the accommodating space 38, the limitation part 3004 of the light guide member 300 contacts the side of the display panel 34 so that the display panel 34 is tightly disposed in the accommodating space 38.

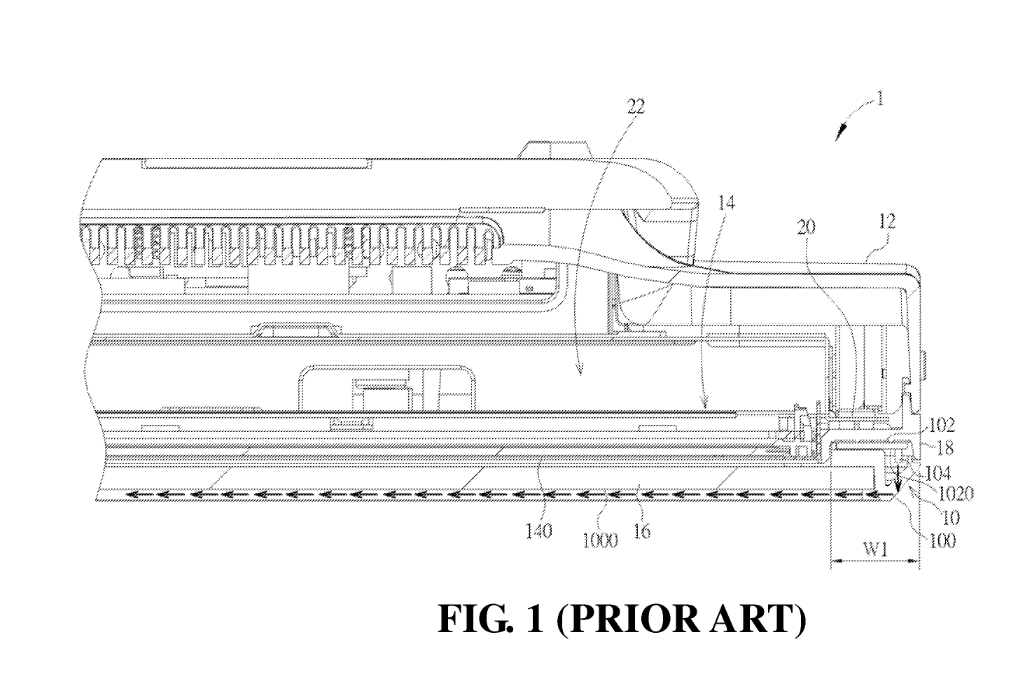

In this invention, an angle θ is included between the arrangement plane 3020 of the circuit board 302 and the touch plane 3000, wherein the included angle θ is larger than 0 degree and smaller than or equal to 90 degrees. That is the arrangement plane 3020 of the circuit board 302 is not substantially parallel to the touch plane 3000 so as to decrease the frame width W2 of the display device 3, i.e. the side width of the light guide member 300. Preferably, as shown in FIG. 3, the arrangement plane 3020 of the circuit board 302 is substantially vertical to the touch plane 3000, i.e. the included angle θ is equal to 90 degrees, so that the frame width W2 of the display device 3 is decreased to its minimum value or dimension. As shown by comparing FIG. 1 and FIG. 3, the frame width W2 of the display device 3 according to the embodiment of present invention is obviously less than the frame width W1 of the display device 1 according to the prior art (which means that the respective display devices shown in FIG. 1 and FIG. 3. Please note that since the display plane 340 of the display panel 34 is substantially parallel to the touch plane 3000, the angle included between the arrangement plane 3020 of the circuit board 302 and the display plane 340 is substantially equal to the included angle θ.

In practical application, an array of the infrared transmitters 304 and the corresponding array of the infrared receivers (not shown) are disposed in the inner side of the light guide member 300. When the infrared transmitters 304 emit infrared rays, the light guide member 300 guides the infrared rays to the touch plane 3000 to form an infrared net (of rays). As long as a user touch the touch plane 3000 to interrupt one or more of the infrared rays, the processor (not shown) of the display device 3 analyzes the interrupted infrared ray(s) to determine the touch position. Please note that the infrared touch technology is well known by these persons skilled in the art, and is therefore not described in details herein.

In conclusion, in this invention, an angle larger than 0 degree and smaller than or equal to 90 degrees is included between the arrangement plane of the circuit board and the touch plane, i.e. the arrangement plane of the circuit board is not substantially parallel to the touch plane so as to decrease the frame width of the display device. In this way, the display device according to this invention is suitable for the narrow width design. Furthermore, in this invention, since the back casing and the light guide member are combined with each other directly without having or including the middle frame that is expressly required in the conventional display device according to the prior art, the assembly efficiency of the display device of the present invention is improved and the manufacturing cost is decreased.

Those skilled in the art will readily observe that numerous modifications and alterations of the device and method may be made while retaining the teachings of the invention.

What is claimed is:

1. A display device comprising:
an infrared touch module, comprising a light guide member, a circuit board and an infrared transmitter, wherein the circuit board is disposed on the light guide member, the infrared transmitter is disposed on an arrangement plane of the circuit board, the light guide member defines a touch plane, an angle is included between the arrangement plane and the touch plane, and the included angle is larger than 0 degree and smaller than or equal to 90 degrees;
a back casing, combined with the light guide member so that an accommodating space is formed between the light guide member and the back casing; and
a display panel, disposed in the accommodating space, the display panel having a display plane and the display plane of the display panel being substantially parallel to the touch plane defined by the light guide member.

2. The display device of claim 1, wherein the light guide member has a first combination part, the back casing has a second combination part, and the first combination part of the light guide member and the second combination part of the back casing are combined with each other so that the light guide member and the back casing are combined with each other.

3. The display device of claim 2, wherein the first combination part is one of a latch and a hole, the second combination part is the other of the latch and the hole, and the light guide member and the back casing are combined with each other through the latch and the hole.

4. The display device of claim 1, wherein the light guide member has a limitation part, the limitation part contacts the display panel so that the display panel is tightly disposed in the accommodating space.

5. The display device of claim 1, further comprising a protective glass disposed on the light guide member, wherein the protective glass has a surface that lies substantially the same as the touch plane defined by the light guide member.

6. The display device of claim 1, wherein a light output direction of the infrared transmitter is substantially parallel to the arrangement plane of the circuit board.

7. The display device of claim 1, wherein the arrangement plane of the circuit board is substantially vertical to the touch plane.

8. An infrared touch module comprising:
a light guide member, defining a touch plane;
a circuit board, disposed on the light guide member; and
an infrared transmitter, disposed on an arrangement plane of the circuit board, wherein an angle is included between the arrangement plane and the touch plane, and the included angle is larger than 0 degree and smaller than or equal to 90 degrees.

9. The infrared touch module of claim 8, wherein a light output direction of the infrared transmitter is substantially parallel to the arrangement plane of the circuit board.

10. The infrared touch module of claim 8, wherein the arrangement plane of the circuit board is substantially vertical to the touch plane.
